(19) United States
(12) Patent Application Publication
(10) Pub. No.: US 2012/0194450 A1
(43) Pub. Date: Aug. 2, 2012

(54) MULTICONTACT TACTILE SENSOR WITH INTERMEDIATE RESISTIVE LAYER

(75) Inventors: Guillaume GONCALVES, Bordeaux (FR); Guillaume Wantz, Pessac (FR); Lionel Hirsch, Pessac (FR)

(73) Assignees: STANTUM, Bordeaux (FR); INSTITUT POLYTECHNIQUE DE BORDEAUX, Talence Cedex (FR); UNIVERSITE DE BORDEAUX 1, Talence (FR); CENTRE NATIONAL DE LA RECHERCHE SCI. (CNRS), Paris Cedex 16 (FR)

(21) Appl. No.: 13/233,615

(22) Filed: Sep. 15, 2011

(30) Foreign Application Priority Data
Jan. 31, 2011 (FR) 11 50741

(51) Int. Cl. G06F 3/041; G01R 27/08; B82Y 99/00

(52) U.S. Cl. 345/173; 324/693; 977/773

(57) ABSTRACT

A multicontact tactile sensor including an upper structure having first conductive tracks arranged in rows, a lower structure having second conductive tracks arranged in columns, spacers positioned between the upper structure and the lower structure; and an intermediate layer positioned on at least one of the first or the second conductive tracks, the intermediate layer made of a semiconductor metal oxide.

### CROSS-REFERENCE TO RELATED APPLICATIONS

This application claims the benefit under 35 U.S.C. §119 from French Application No. 11 50741, filed Jan. 31, 2011, the entire content of which is incorporated herein by reference.

### BACKGROUND OF THE INVENTION

The present invention concerns a multicontact tactile sensor. It also concerns a tactile screen implementing a multicontact tactile sensor.

### BRIEF DESCRIPTION OF THE RELATED ART

A tactile sensor is described, for example, in document EP 1 719 047. This sensor comprises an upper structure having conductive tracks arranged in rows and a lower structure having conductive tracks arranged in columns. Spacers are positioned between the upper structure and the lower structure to insulate the conductive tracks. When a user presses on the surface of such a tactile sensor, the conductive tracks of the upper structure make contact with the conductive tracks of the lower structure in the zones located between the spacers. A contact resistance is thus created in each cell corresponding to the intersections of the conductive rows and columns.

Document EP 1 719 047 describes in particular a method of sequential scanning of the conductive rows and columns, allowing one to detect the position of the points of contact corresponding to the zones where a user presses down on the sensor.

One also knows from document FR 2 942 329 such a sensor further comprising an intermediate resistive layer positioned between the spacers on the one hand and a layer, whether the upper conductive layer or the lower conductive layer on the other hand.

The presence of this resistive material between the two conductive layers makes it possible to increase the contact resistance at each point of contact. It is possible to thus limit the recirculation of current between the rows and the columns to eliminate the problems of masking and orthogonality between the points of contact.

One will advantageously refer to the specification of this document FR 2 942 329 for the detailed explanation of these problems.

Document FR 2 942 329 describes an intermediate resistive layer of silicone whose thickness is around 300 μm and having a resistivity of 640Ω·m. This intermediate silicone layer plays its part perfectly to diminish the problems of masking and orthogonality between the points of contact.

### BRIEF SUMMARY OF THE INVENTION

The purpose of the present invention is to propose a multicontact tactile sensor having an improved structure that is easier to implement. For this, the present invention concerns a multicontact tactile sensor comprising an upper structure having conductive tracks arranged in rows, a lower structure having conductive tracks arranged in columns, spacers positioned between said upper structure and said lower structure, and at least one intermediate resistive layer positioned on the conductive tracks of at least one structure, whether the upper structure or the lower structure.

According to the invention, the intermediate layer is a semiconductor metal oxide layer. By virtue of the use of the semiconductor properties of this intermediate layer of metal oxide, it is possible to improve the electrical characteristics of the tactile sensor, and especially to limit the recirculation of current between the rows and the columns. Advantageously, the intermediate layer has a thickness between 50 and 300 nm.

The use of a semiconductor metal oxide layer makes it possible to implement a thin intermediate layer between the upper and lower structures of the multicontact tactile sensor.

In the case of a transparent multicontact tactile sensor, this thin semiconductor metal oxide layer makes it possible to obtain a tactile sensor having better optical characteristics. One can thus gain in terms of transparency up to 2-3% as compared to a multicontact tactile sensor of the prior art.

According to one practical embodiment of the invention, the intermediate layer comprises nanoparticles of titanium dioxide (TiO2). In practice, the intermediate layer is made of a material with resistivity between 10³ and 10⁶Ω·m. The use of an intermediate layer of elevated resistivity between the conductive tracks of the upper and lower structures of the multicontact tactile sensor makes it possible to increase the electrical contact resistance at the points of contact.

By virtue of the increased electrical contact resistance between the rows and the columns, the recirculation of current through these rows and columns is limited.

In one embodiment of the invention, the intermediate layer is structured in rows on the conductive tracks of the upper structure or it is structured in columns on the conductive tracks of the lower structure. This structuring of the intermediate layer makes it possible to avoid the problems of electrical leakage between the adjacent columns or rows, these being insulated from each other.

According to a second aspect, the present invention concerns a touch screen comprising a display screen disposed beneath a multicontact tactile sensor according to the invention. This touch screen has characteristics and advantages similar to those described above in regard to the multicontact tactile sensor.

Other features and advantages of the invention also will become apparent in the following description.

### BRIEF DESCRIPTION OF THE DRAWINGS

In the attached drawings, given as nonlimiting examples:

FIG. 1 is a sectional view of a multicontact tactile sensor according to a first embodiment of the invention;

FIG. 2 is a sectional view of a multicontact tactile sensor according to a second embodiment of the invention;

FIG. 3 is an exploded perspective view of the multicontact tactile sensor of FIG. 1;

FIG. 4 is a sectional view of a multicontact tactile sensor according to a third embodiment of the invention;

FIG. 5 is a sectional view of a multicontact tactile sensor according to a fourth embodiment of the invention; and

FIG. 6 is an exploded perspective view of the multicontact tactile sensor of FIG. 4.

### DETAILED DESCRIPTION OF THE INVENTION

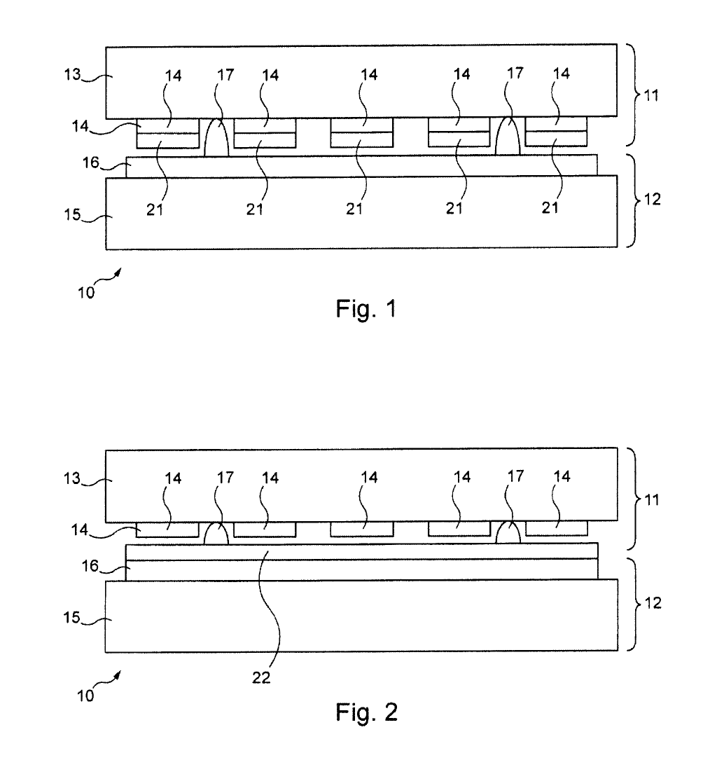

We shall first describe a first embodiment of a multicontact tactile sensor 10, making reference to FIGS. 1 and 3.

It will be noted that in all of the figures the same numerical references relate to similar technical elements.

The multicontact tactile sensor 10 illustrated in FIG. 1 comprises an upper structure 11 and a lower structure 12 disposed facing each other. The upper structure 11 is constituted, for example, from a film 13 of polyethylene terephthalate (PET), beneath which are arranged conductive tracks 14. These conductive tracks are made of a conductor material and structured along rows in the plane of the upper structure 11, as shown in FIG. 3.

The lower structure 12 is constituted, for example, from a glass plate 15 on which are found conductive tracks 16. These conductive tracks 16 are arranged in columns in the plane of the lower structure 12. The conductor material used to make the conductive tracks 14, 16 is, for example, a transparent conductive oxide, such as indium tin oxide (ITO).

Alternatively, one can also use other translucid conductive materials, such as zinc oxide doped with aluminum (ZnO:Al) or a tin oxide doped with fluorine (SnO2:F). Of course, the notions of rows and columns described above in regard to the upper structure 11 and the lower structure 12 are relative notions and can be interchanged, depending on the orientation of the sensor 10. It is important to create a matrix array of conductive tracks 14, 16 such that the conductive tracks arranged in rows 14 of the upper structure 11 are perpendicular to the conductive tracks arranged in columns 16 of the lower structure 12.

Preferably, the multicontact tactile sensor 10 is transparent. In this embodiment, the layers of conductive tracks 14, 16 made of ITO, the film of PET 13 and the glass plate 15 are transparent.

This embodiment is especially advantageous when the tactile sensor 10 is intended to be combined with a display screen disposed beneath this multicontact tactile sensor to form a touch screen.

Spacers 17 are furthermore arranged between the upper structure 11 and the lower structure 12. These spacers 17 are arranged so that, when no pressure is exerted on the upper structure 11, the conductive tracks 14 arranged in rows do not make contact with the conductive tracks 16 arranged in columns.

In order to increase the contact resistance between the rows 14 and the columns 16, it is provided to position an intermediate layer 21 in the multicontact tactile sensor 10 on the conductive tracks of at least one of the upper 11 or lower 12 structures.

In the first embodiment illustrated in FIGS. 1 and 3, the intermediate layer 21 is positioned on the conductive tracks 14 of the upper structure 11.

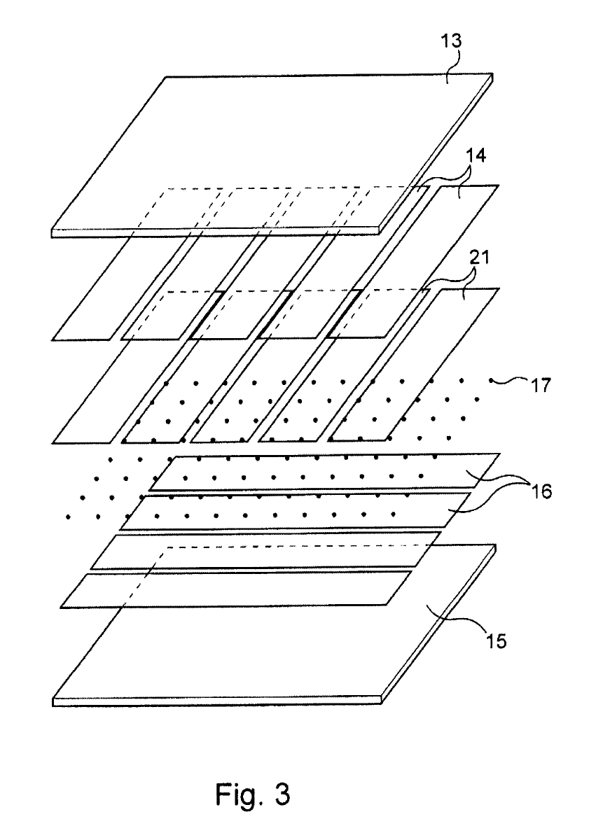

A second embodiment is illustrated in FIG. 2. The second embodiment is in all points identical to that described previously in connection with FIG. 1, only the positioning of the intermediate layer 22 being modified. This intermediate layer 22 is placed here on the conductive tracks 16 of the lower structure 12.

Thus, in the first embodiment illustrated in FIG. 1, the intermediate layer 21 is structured in rows on the conductive tracks arranged in rows 14 of the upper structure 11. On the contrary, in the second embodiment illustrated in FIG. 2, the intermediate layer 22 is structured in columns on the conductive tracks arranged in columns 16 of the lower structure 12.

In order to improve the electrical characteristics of the multicontact tactile sensor 10, the intermediate layer 21, 22 is made from a semiconductor metal oxide layer.

Preferably, this intermediate layer 21, 22 comprises nanoparticles of titanium dioxide TiO2.

One thus utilizes the semiconductor properties of these particles of titanium dioxide TiO2 in order to increase the contact resistance between the rows and the columns 16 of the multicontact tactile sensor 10.

This intermediate layer 21, 22 furthermore allows preserving the transparency of the tactile sensor 10 in the embodiments previously described.

Moreover, it preferably has a resistivity between 10³ and 10⁶Ω·m.

By virtue of this elevated resistivity of the intermediate layer, the contact resistance is increased.

In the prior art, when contact is made at the rows 14 and columns 16 of ITO, the contact resistance is very slight, on the order of several Ohms.

Here, by virtue of the presence of the semiconductor metal oxide layer such as titanium dioxide TiO2, the resistance at the points of contact is much more elevated, on the order of several thousand Ohms.

By virtue of the elevated resistivity of this intermediate layer 21, 22, especially when it is made from nanoparticles of titanium dioxide TiO2, it can play its role even at very slight thickness. This intermediate layer 21, 22 is a thin layer, having a slight thickness and being, for example, between 50 and 300 nm, and typically basically equal to 100 nm.

It will be noted that in the two embodiments illustrated in FIGS. 1 and 2, the spacers 17 positioned between the upper structure 11 and the lower structure 12 are arranged so that, when no pressure is exerted on the upper structure 11 of the multicontact tactile sensor 10, the conductive tracks arranged in rows 14 covered by the intermediate layer 21 do not make contact with the conductive tracks arranged in columns 16, and the conductive tracks arranged in columns 16 covered by the intermediate layer 22 do not make contact with the conductive tracks arranged in rows 14.

In these embodiments where the intermediate layer 21, 22 is structured in rows or in columns, it is preferably structured at the same time as the conductive tracks of ITO created on the glass plate 15 and the film of PET 13, respectively.

The structuring of this intermediate layer 21, 22 makes it possible to avoid the problems of electrical leakage between the consecutive columns or rows, since they are thus insulated from each other.

Of course, in another embodiment, the tactile sensor could have simultaneously an intermediate layer 21 arranged on the rows 14 of the upper structure 11 and an intermediate layer 22 arranged on the columns 16 of the lower structure 12.

One thus obtains a homogeneous contact between two semiconductor metal oxide layers of the same material, and for example between two layers of titanium dioxide TiO2.

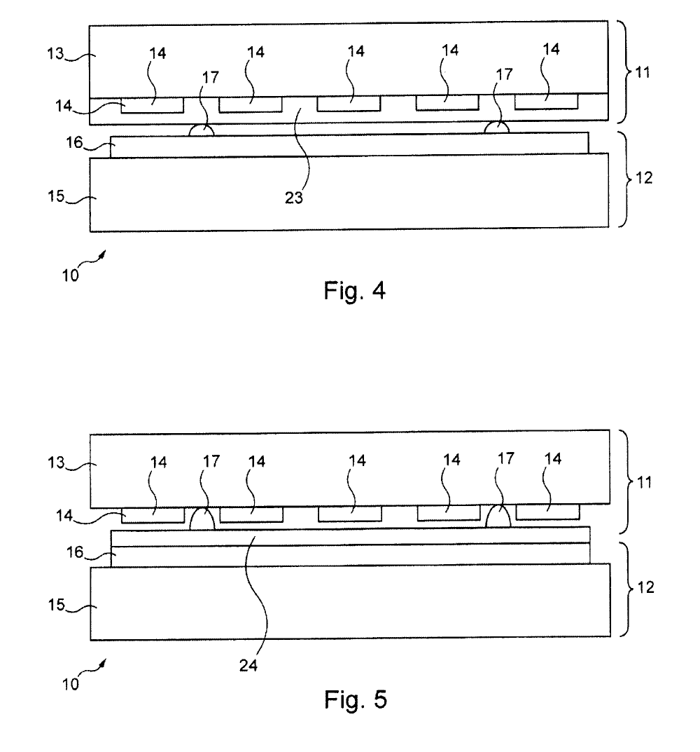

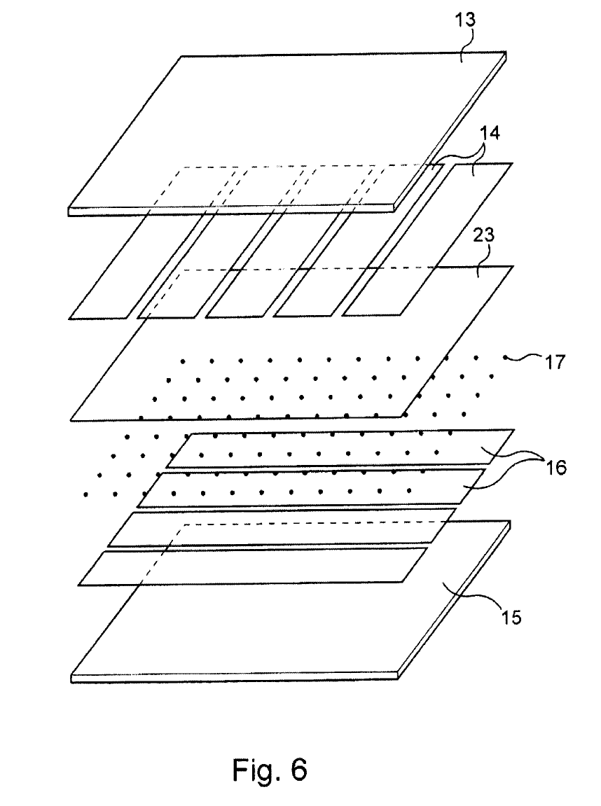

FIGS. 4 to 6 illustrate a third and fourth embodiment of the invention in which the intermediate layer 23, 24 is disposed on the conductive tracks 14 of the upper structure 11 (FIGS. 4 and 6) or on the conductive tracks 16 of the lower structure 11 (FIG. 5), but without structuring in the form of rows or columns.

These embodiments are particularly advantageous for making the intermediate layer 23, 24 invisible and thus augmenting the quality of transparency of the multicontact tactile sensor 10.

Thus, as illustrated in FIGS. 4 and 6, an intermediate layer 23 is positioned on the conductive tracks arranged in rows 14 of the upper structure 11.

The conductive tracks 14 are thus embedded in the thickness of the intermediate layer 23.

Alternatively, in the fourth embodiment as illustrated in FIG. 5, the intermediate layer 24 is positioned on the conductive tracks arranged in columns 16 of the lower structure 12.

The conductive tracks arranged in columns 16 are thus embedded in the intermediate layer 24.

Of course, the tactile sensor could comprise simultaneously one intermediate layer 23 arranged on the upper structure 11 and one intermediate layer 24 arranged on the lower structure 12.

Various manufacturing techniques can be used to produce the multicontact tactile sensor 10 as described above in regard to FIGS. 1 to 6.

The traditional techniques of silk screening or engraving can be used to make the conductive tracks 14, 16 of ITO on the glass plate 15 and the film of PET 13.

The intermediate layer 21-24 can be made from a solution of nanoparticles deposited by a sol-gel process, by polymerization of the solution.

The thickness of the intermediate layer 21-24 thus produced can be controlled by the concentration of the solution used. Thus, by increasing the concentration of nanoparticles, the thickness of the intermediate layer 21-24 is increased.

As a purely illustrative example, one can use an aqueous solution of nanoparticles of titanium dioxide TiO2 having a concentration of 15% by weight.

These nanoparticles are dispersed in the aqueous solution with 0.2% of SDS (sodium dodecyl sulfate).

Such an aqueous solution of nanoparticles makes it possible to create an intermediate layer having a thickness basically equal to 130 nm by using, for example, a technique of application by imprinting with a doctor blade.

As previously mentioned, the intermediate layer 21-24 can be deposited either on the lower structure 12 formed from a glass plate 15 and/or on the upper structure 11 formed from a film of PET 13.

Preferably, however, the intermediate layer 22, 24 is deposited on the conductive tracks 16 of the lower structure 12 made on the glass plate 15.

The techniques of deposition of the solution of nanoparticles can make use of the techniques of spray-coating, spin-coating, or cast-coating.

These techniques of application by coating and then polymerization are well adapted to large surfaces, and are easy to implement on the production line.

Alternatively, a thin semiconductor metal oxide layer of TiO2 type can also be laid down by chemical vapor deposition (CVD), by physical vapor deposition (PVD) or by electroplating.

In the embodiments illustrated in FIGS. 1 to 3, the intermediate layer 21, 22 is deposited on a conductive layer of ITO, the structuring in rows 14 or in columns 16 being then done simultaneously on the conductive layer of ITO and the intermediate layer of semiconductor metal oxide, for example, by engraving.

On the contrary, in the embodiments described with regard to FIGS. 4 to 6, the conductive layers of ITO are first structured in rows and columns prior to depositing of the intermediate layer 23, 24.

Finally, the spacers 17 are deposited, for example by silk screening, either on the lower structure 12 or on the upper structure 11.

Preferably, these spacers are disposed between the rows 14 or the columns 16.

They can also be disposed directly on the intermediate layer 23, 24 when this intermediate layer is continuous in the plane of the upper structure 11 or the lower structure 12.

1. A multicontact tactile sensor comprising:
an upper structure having first conductive tracks arranged in rows;
a lower structure having second conductive tracks arranged in columns;
spacers positioned between said upper structure and said lower structure; and
an intermediate layer positioned on at least one of the first or the second conductive tracks, the intermediate layer made of a semiconductor metal oxide.

2. The multicontact tactile sensor according to claim 1, wherein said intermediate layer has a thickness between 50 nm and 300 nm.

3. The multicontact tactile sensor according to claim 1, wherein said intermediate layer includes nanoparticles that are made of Titanium Dioxide (TiO₂).

4. The multicontact tactile sensor according to claim 1, wherein the intermediate layer is made of a material having a resistivity between 10³ Ωm and 10⁶ Ωm.

5. The multicontact tactile sensor according to claim 1, wherein said lower and upper structures and said intermediate layer are transparent.

6. The multicontact tactile sensor according to claim 1, wherein said intermediate layer is structured as rows that are located on the first conductive tracks of said upper structure.

7. The multicontact tactile sensor according to claim 1, wherein said intermediate layer is structured as columns that are located on the second conductive tracks of said lower structure.

8. The multicontact tactile sensor according to claim 1, wherein at least one of the first conductive tracks of the upper structure or the second conductive tracks of the lower structure are made of Indium Tin Oxide (ITO).

9. A touch screen comprising a display screen disposed beneath a multicontact tactile sensor, the multicontact tactile sensor including:
an upper structure having first conductive tracks arranged in rows;
a lower structure having second conductive tracks arranged in columns;
spacers positioned between said upper structure and said lower structure; and
an intermediate layer positioned on at least one of the first or the second conductive tracks, the intermediate layer made of a semiconductor metal oxide.
